(19) United States
(12) Patent Application Publication
(10) Pub. No.: US 2022/0369449 A1
(43) Pub. Date: Nov. 17, 2022

(54) ON-BOARD TELEMATIC DEVICE WITH INTEGRATED COOLING FOR A MOTOR VEHICLE

(71) Applicant: VALEO COMFORT AND DRIVING ASSISTANCE, Créteil (FR)

(72) Inventors: Patrick Klein, Créteil (FR); Renato Curcio, Créteil (FR)

(73) Assignee: VALEO COMFORT AND DRIVING ASSISTANCE, Créteil (FR)

(21) Appl. No.: 16/631,268

(22) PCT Filed: Jul. 17, 2018
(86) PCT No.: PCT/EP2018/069445

§ 371 Date: Apr. 10, 2020

(30) Foreign Application Priority Data
Jul. 17, 2017 (FR) 1756748

(51) Int. Cl. H05K 1/02; H01Q 1/32

(52) U.S. Cl. CPC H05K 1/021; H01Q 1/325

(57) ABSTRACT

An on-board telematic device intended to be attached to a metal part (3) of a body of a motor vehicle comprises, according to the invention, a housing (1) integrating a printed circuit board (5), a face of which supports at least one electronic power component (6), a radiofrequency antenna (7), intended to extend through an opening of the metal part (3), and a metal screen (9) interposed between a lower part of the antenna (7), on the one hand, and the printed circuit board (5) and said at least one component, on the other hand, in order to isolate the antenna from parasitic emissions. The component (6) is placed in line with the metal screen (9) and in thermal contact with a portion of said screen, and said screen (9) is made of a thermally conductive material so as to form a thermal transfer means between the electronic power component (6) and the metal part (3).

The present invention relates in general to onboard telematic devices intended to be fitted to motor vehicles, and more specifically to the cooling of power electronic components incorporated within such onboard telematic devices.

Onboard telematic devices increasingly include functions exhibiting high power dissipation employing components exhibiting low tolerances with respect to temperature. By way of example, a telematic device with NAD (network access device) functionality, incorporating a cellular modem, may dissipate several watts of power, with junction temperatures for the components which must be below 120° C.

An onboard telematic device may be complex to design in terms of thermal power dissipation management, particularly if the device is to be placed in locations on the motor vehicle that are likely to be subject to high temperatures, such as for example under the roof of the vehicle where the ambient temperature may approach 95° C.

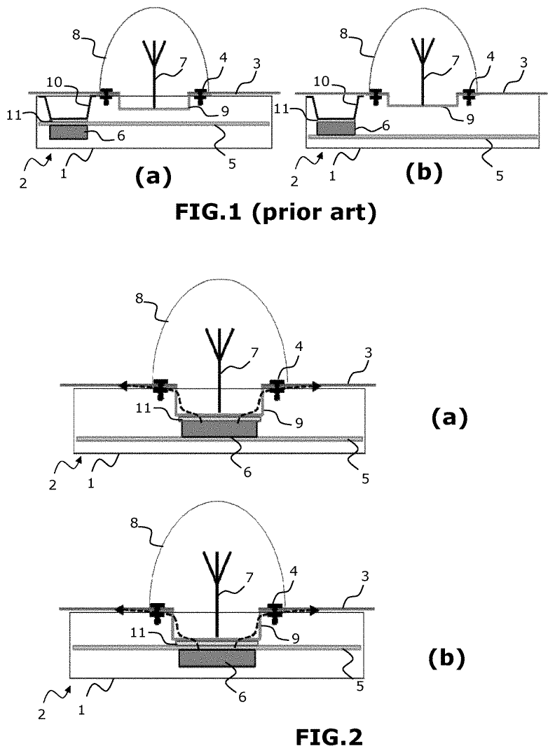

One conventional means for cooling a power electronic component is to use a heatsink incorporated within the onboard telematic device, as shown schematically in FIG. 1. In this figure, a housing 1 for an onboard telematic device 2 is illustrated attached under the roof 3 of a motor vehicle by means of fastening bolts 4. The device 2 includes, incorporated within the housing 1, a printed circuit board 5 and a power electronic component 6 attached to the printed circuit board 5. The power electronic component 6 may be attached to the top face of the printed circuit board 5 (as is the case in FIG. 1(a)), or to its bottom face (as is the case in FIG. 1(b)). The device further includes, for the purpose of exchanging data externally, a radiofrequency transceiving antenna 7, which extends vertically outwards through an opening made in the body so as to emerge from the roof 3. A radome 8 preferably protects the antenna from foreign bodies. A metal screen 9 interposed between the lower part of the antenna 7 on one side and the printed circuit board 5 and the components borne thereby on the other side allows the antenna to be insulated from the electronic components, parasitic emissions from which could affect the transceiving performance of the antenna. This metal screen 9 is generally attached to the roof 3, which is also made of metal, for example by means of the same fastening bolts 4 as those used to hold the housing 1, so as to afford good electrical contact and thus to provide continuity of the shielding afforded by the screen 9. More specifically, the metal screen 9 includes a rim that bears against an outer face of the housing 1 and is peripheral to the opening, and the device is capable of being attached to the metal part by means of the fastening bolts passing through the rim and the outer face of the housing together. Lastly, to cool the power electronic component 6, the housing 1 incorporates, in line with the component and in thermal contact with an inner face of the upper part of the housing, a heatsink 10, the metal parts of which enhance the heat exchange between the component 6 and the air and thus limit the rise in temperature of the component. A thermal interface-forming layer 11 is preferably interposed between the lower part of the heatsink 10 and the upper part of the component (case (b)) or the printed circuit board (case (a)) in order to promote heat exchange.

In another known embodiment, the heatsink 10 is replaced with a heat pipe allowing heat exchange between the component 6 and other, external elements (not shown).

These known solutions all have an effect on cost, bulk and weight and require the addition of a heatsink or a heat pipe.

In other known embodiments, which avoid the use of a heatsink 10, the housing 1 is chosen so as to be made from a material exhibiting good thermal conductivity and to be formed so that it is in line with the component 6 in order to perform the same cooling function as the heatsink 10.

However, this solution is still expensive due to the choice of material exhibiting good thermal conductivity which then has to be used for the entire housing.

The object of the present invention is to overcome the drawbacks of the solutions provided so far.

This object is achieved according to the invention, the subject of which is an onboard telematic device that is intended to be attached to a metal part of a body of a motor vehicle, including a housing incorporating a printed circuit board, one face of which bears at least one power electronic component, a radiofrequency transceiving antenna, which is intended to extend through an opening in the metal part, and a metal screen that is interposed between a lower part of the antenna on one side and the printed circuit board and said at least one component in order to insulate the antenna from parasitic emissions, said screen being intended to be attached between said metal part and the housing so as to provide electrical continuity, in which device said at least one component is placed in line with the metal screen and in thermal contact with a portion of said screen, and said screen is made of thermally conductive material so as to form a means for heat transfer between the power electronic component and the metal part.

Besides the main features that have just been mentioned in the preceding paragraph, the method according to the invention may have one or more additional features from among the following:
the metal screen preferably includes a rim that bears against an outer face of the housing and is peripheral to the opening, and the device is capable of being attached to the metal part by means of fastening bolts passing through said rim and the outer face of the housing together;
the thermal conductivity of the conductive material is preferably higher than or equal to 50 W·m⁻¹·K⁻¹;
the conductive material is for example steel, aluminum or zamak;
in one embodiment, said at least one power electronic component is borne by a face of the printed circuit board that is directly facing the portion of said screen, and a thermal interface-forming layer is interposed between a lower part of the portion of said screen and the upper part of said component;
as a variant, said at least one power electronic component is borne by a first face of the printed circuit board opposite a second face of the board that is directly facing the portion of said screen, and a thermal interface-forming layer is interposed between a lower part of the portion of said screen and the first face of the printed circuit board;
in another embodiment, the rim of the metal screen runs parallel to the printed circuit board so as to form one face of said housing;
said rim may include a projection extending into the interior of the housing, with a lower portion of said projection placed in line with and in thermal contact with another power electronic component borne by said printed circuit board.

The invention will be better understood upon reading the following description, given with reference to the appended figures, in which:

FIG. 1, which has already been described above, schematically illustrates two onboard telematic devices with integrated cooling for a power electronic component in position attached to the roof of a motor vehicle;

FIG. 2 schematically illustrates a first embodiment of a telematic device according to the invention, in position attached to the roof of a motor vehicle, and according to two variant embodiments;

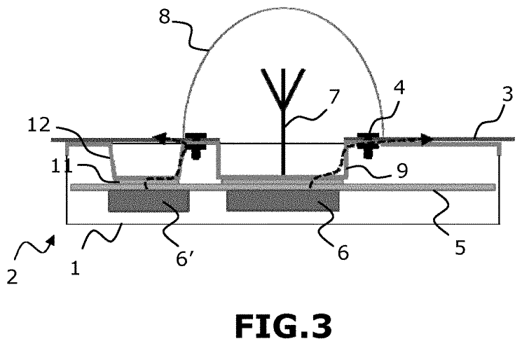

FIG. 3 schematically illustrates a second embodiment of a telematic device according to the invention, in position attached to the roof of a motor vehicle.

In all of the figures, the various common elements bear the same reference symbols.

The principle of the invention is based on the presence, in an onboard telematic device 2 such as described above with reference to FIG. 1, of the metal screen 9, the primary function of which is to protect the radiofrequency communication antenna 7 from interference generated by the electronic components of the device. According to the invention, what is proposed is to assign a second function to this screen by also using it as a vector for thermal energy between the power electronic component and the metal portion of the vehicle body, for example the vehicle roof, to which the device is to be attached.

In doing so, the metal screen 9 becomes a thermal conductor and draws the heat to be dissipated to the metal body portion which then acts as a heatsink.

A first embodiment will now be described with reference to FIG. 2, which shows an onboard telematic device 2 already attached to the metal portion of the vehicle body, here the roof 3. This device includes all of the elements already described with reference to FIG. 1. However, unlike in FIG. 1, the power electronic component 6 that is to be cooled is placed in line with the metal screen 9 and in thermal contact with a portion of said screen. Additionally, the screen 9 is made of thermally conductive material so as to form a means for heat transfer between the power electronic component 6 and the metal part 3.

The conductive material is preferably chosen from metallic materials exhibiting a thermal conductivity that is higher than or equal to 50 W·m⁻¹·K⁻¹. For example, it is possible to use steel, aluminium or zamak, which is an alloy of zinc, aluminum and of magnesium and copper.

In the case of FIG. 2(a), the power electronic component 6 is borne by the top face of the board 5, more generally by the face of the printed circuit board 5 that is directly facing the portion of the screen 9. In this case, a thermal interface-forming layer 11 is preferably interposed between a lower part of the portion of the screen 9 and the upper component part.

In the variant of FIG. 2(b), the power electronic component 6 is borne by the other face of the printed circuit board, i.e. the face of the printed circuit board 5 opposite that which is directly facing the portion of the screen 9. Here again, a thermal interface-forming layer 11 is preferably interposed, this time between the lower part of the portion of said screen 9 and the face of the printed circuit board 5 that is directly facing the portion of the screen 9.

In both variants, the layer 11 is formed of a thermal grease, of a thermal adhesive, of a thermal paste or of any other material allowing the space between the elements to be filled and good thermal conduction to be provided.

In any case, it is the metal body portion, here the roof, which acts as a heatsink for the thermal energy passing therethrough, as indicated by the dashed arrows, between the component 6 and the body via the metal screen 9.

In a second embodiment illustrated schematically in FIG. 3, the rim of the metal screen 9 is further sized such that it runs parallel to the printed circuit board 5 so as to form one face (in this example the upper face) of the housing 1.

One advantage of this second embodiment is that the screen 9 may also be used as a thermal energy vector for other components of the device 2 that are to be cooled, such as a second power electronic component 6′. This second component 6′ is here placed in line with and in thermal contact with a lower portion of a projection 12 of the rim that extends into the interior of the housing 1.

1. An onboard telematic device that is intended to be attached to a metal part (3) of a body of a motor vehicle, including a housing (1) incorporating a printed circuit board (5), one face of which bears at least one power electronic component (6), a radiofrequency transceiving antenna (7), which is intended to extend through an opening in the metal part (3), and a metal screen (9) that is interposed between a lower part of the antenna (7) on one side and the printed circuit board (5) and said at least one component in order to insulate the antenna from parasitic emissions, said screen being intended to be attached between said metal part (3) and the housing (1) so as to provide electrical continuity, in which device said at least one component (6) is placed in line with the metal screen (9) and in thermal contact with a portion of said screen, and said screen (9) is made of thermally conductive material so as to form a means for heat transfer between the power electronic component (6) and the metal part (3).

2. The device as claimed in claim 1, characterized in that the metal screen (9) includes a rim that bears against an outer face of the housing and is peripheral to the opening, and in that the device is capable of being attached to the metal part by means of fastening bolts (4) passing through said rim and the outer face of the housing (1) together.

3. The device as claimed in either of the preceding claims, characterized in that the thermal conductivity of the conductive material is higher than or equal to 50 W·m⁻¹·K⁻¹.

4. The device as claimed in claim 3, characterized in that the conductive material is steel.

5. The device as claimed in claim 3, characterized in that the conductive material is aluminum.

6. The device as claimed in claim 3, characterized in that the conductive material is zamak.

7. The device as claimed in any one of the preceding claims, characterized in that said at least one power electronic component (6) is borne by a face of the printed circuit board (5) that is directly facing the portion of said screen (9), and in that a thermal interface-forming layer (11) is interposed between a lower part of the portion of said screen (9) and the upper part of said component.

8. The device as claimed in any one of claims 1 to 7, characterized in that said at least one power electronic component (6) is borne by a first face of the printed circuit board (5) opposite a second face of the board (5) that is directly facing the portion of said screen (9), and in that a thermal interface-forming layer (11) is interposed between a lower part of the portion of said screen (9) and the first face of the printed circuit board (5).

9. The device as claimed in any one of claims 2 to 8, characterized in that the rim of the metal screen (9) runs parallel to the printed circuit board (5) so as to form one face of said housing (1).

10. The device as claimed in claim 9, characterized in that said rim includes a projection extending into the interior of the housing (1), with a lower portion of said projection placed in line with and in thermal contact with another power electronic component (6′) borne by said printed circuit board (5).
